(19) United States
(12) Patent Application Publication
(10) Pub. No.: US 2019/0373187 A1
(43) Pub. Date: Dec. 5, 2019

(54) PORTABLE IMAGE CAPTURE DEVICE

(71) Applicant: LENOVO Enterprise Solutions (Singapore) PTE. LTD., New Tech Park (SG)

(72) Inventor: CheKim Chhuor, Shanghai (CN)

(21) Appl. No.: 16/427,651

(22) Filed: May 31, 2019

(30) Foreign Application Priority Data
May 31, 2018 (CN) 201810552764.X

(51) Int. Cl. H04N 5/341; H01L 27/146; G06F 3/041; G06F 3/0484

(52) U.S. Cl. CPC H04N 5/341; G06F 3/04845; G06F 3/0412; H01L 27/14605

(57) ABSTRACT

A portable image capture device includes a sensor array for capturing a basis image. The sensor array is symmetrical about two perpendicular axes so that the basis image is symmetrical about two perpendicular axes. The portable image capture device includes an image storage module for storing a source image corresponding to the basis image, an image selector for receiving a selected aspect ratio, a pixel modifier module for producing a modified image at the selected aspect ratio, where the modified image is produced from the source image, and a display for displaying the modified image.

### CROSS-REFERENCE TO RELATED APPLICATIONS

This patent application claims priority to China Patent Application No. 201810552764.X filed on May 31, 2018 for CheKim Chhuor, the entire contents of which are incorporated herein by reference for all purposes.

### FIELD

The subject matter disclosed herein relates to portable image capture devices.

### BACKGROUND

In recent years, smartphones have become the main medium by which photographs are taken. Smartphones are generally designed to be held in portrait orientation between the user's mouth and ear. The camera lens is typically located closer to the ‘ear’ end, or top, of the phone as opposed to the ‘mouth’ end, or bottom, of the phone. Thus, as a result of the design of smartphones, it is generally more convenient to hold the smartphone in portrait orientation while taking photographs, rather than in landscape orientation.

Sometimes it is desirable to change the orientation of the phone, to a landscape orientation, to frame a landscape photo. To accurately hold the smartphone, while keeping hands and fingers generally away from the screen so as to be able to view the photo about to be captured, many smartphones require the user of two hands, to be held steady.

With a regular camera it is the opposite. In many regular cameras, the hardware is designed or built for taking photographs in a landscape orientation. So shooting a portrait oriented photograph requires the user to twist their hand, or twist the tripod on which the camera is mounted.

In either case, existing devices are most conveniently used in a single orientation (portrait or landscape) and are less convenient to use in the other orientation.

When framing a photograph, a decision is made in advance to take the photograph in portrait or landscape orientation. The device is then held in the relevant orientation to take the photograph. Similarly, a decision is made in advance as to the particular aspect ratio (4:3, 3:2, 16:9, 21:9, 1:1) for the photograph. However, on viewing the photograph it may show that the photograph could have been better framed if taken in the other of the two orientations, or at a different aspect ratio.

It is desirable therefore to provide a portable electronic device that removes or ameliorates one or more of the abovementioned problems with existing portable image capture device, or at least to provide a useful alternative.

### BRIEF SUMMARY

A first aspect and a second aspect of the invention have been defined in the independent claims. Some optional features have been defined in the dependent claims. A portable image capture device is disclosed. A method and computer program product also perform the functions of the apparatus. A portable image capture device includes a sensor array for capturing a basis image. The sensor array is symmetrical about two perpendicular axes so that the basis image is symmetrical about two perpendicular axes. The portable image capture device includes an image storage module for storing a source image corresponding to the basis image, an image selector for receiving a selected aspect ratio, a pixel modifier module for producing a modified image at the selected aspect ratio, where the modified image is produced from the source image, and a display for displaying the modified image.

A computer process for producing a modified image includes capturing a basis image that is symmetrical about two perpendicular axes, where the basis image is captured using a sensor array of a portable image capture device and the sensor array is symmetrical about two perpendicular axes, storing a source image corresponding to the basis image in an image storage module in communication with the sensor array, receiving a selected aspect ratio through an image selector, producing a modified image using a pixel modifier module from the source image according to the selected aspect ratio, and displaying the modified image on a display.

In some embodiments, the sensor array is a square array and capturing the basis image comprises capturing a square basis image. In other embodiments, capturing the basis image includes identifying a focal point of the basis image, focussing on the focal point and capturing the basis image. In other embodiments, identifying the focal point includes identifying a particular feature in a field of view of the portable image capture device. In other embodiments, identifying the focal point includes varying a distance between a lens module of the device and sensors of the sensor array and selecting a focal depth when an image sensed by the sensor array is sharpest about a point or a region in a field of view of the portable image capture device. In other embodiments, the computer process includes producing a plurality of altered images, where each altered image of the plurality of altered images corresponds to a respective one of a plurality of predetermined aspect ratios relative to the focal point and displaying the plurality of altered images on the display.

Another embodiment includes a program product the includes a computer readable storage medium that stores code executable by a processor. The executable code includes code to capture a basis image that is symmetrical about two perpendicular axes, where the basis image is captured using a sensor array of a portable image capture device and the sensor array is symmetrical about two perpendicular axes, to store a source image corresponding to the basis image in an image storage module in communication with the sensor array, to receive a selected aspect ratio through an image selector, to produce a modified image using a pixel modifier module from the source image according to the selected aspect ratio, and to display the modified image on a display.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 is a schematic diagram of a computing system or portable image capture device in accordance with present teachings;

FIG. 2A is a first shape for a sensor array of the device of FIG. 1;

FIG. 2B is a second shape for a sensor array of the device of FIG. 1;

FIG. 3 is a basis image and, in many embodiments, a source image where the basis and source images are the same;

FIG. 4A is a first altered image or modified image that reflects a first aspect ratio applied to the source image of FIG. 3, without a reduction in resolution (e.g. made simply be cropping to fit the desired aspect ratio, taking focal point into account);

FIG. 4B is a second altered image or modified image that reflects a second aspect ratio applied to the source image of FIG. 3, without a reduction in resolution;

FIG. 4C is a third altered image or modified image that reflects a third

aspect ratio applied to the source image of FIG. 3, without a reduction in resolution;

FIG. 4D is a fourth altered image or modified image that reflects a fourth aspect ratio applied to the source image of FIG. 3, without a reduction in resolution;

FIG. 4E is a fifth altered image or modified image that reflects a fifth aspect ratio applied to the source image of FIG. 3, without a reduction in resolution;

FIG. 4F is a sixth altered image or modified image that reflects a sixth aspect ratio applied to the source image of FIG. 3, without a reduction in resolution;

FIG. 4G identifies regions in the source image of FIG. 3, that may differ between the basis image and source image in some embodiments;

FIG. 5 is a computer process in accordance with present teachings;

FIG. 6 is an alternative computer process in accordance with present teachings; and

FIG. 7 is a schematic overview of a portable image capture device in accordance with present teachings.

### DETAILED DESCRIPTION

As will be appreciated by one skilled in the art, aspects of the embodiments may be embodied as a system, method or program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a program product embodied in one or more computer readable storage devices storing machine readable code, computer readable code, and/or program code, referred hereafter as code. The storage devices may be tangible, non-transitory, and/or non-transmission. The storage devices may not embody signals. In a certain embodiment, the storage devices only employ signals for accessing code.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in code and/or software for execution by various types of processors. An identified module of code may, for instance, comprise one or more physical or logical blocks of executable code which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different computer readable storage devices. Where a module or portions of a module are implemented in software, the software portions are stored on one or more computer readable storage devices.

Any combination of one or more computer readable medium may be utilized. The computer readable medium may be a computer readable storage medium. The computer readable storage medium may be a storage device storing the code. The storage device may be, for example, but not limited to, an electronic, magnetic, optical, electromagnetic, infrared, holographic, micromechanical, or semiconductor system, apparatus, or device, or any suitable combination of the foregoing.

More specific examples (a non-exhaustive list) of the storage device would include the following: an electrical connection having one or more wires, a portable computer diskette, a hard disk, a random access memory (“RAM”), a read-only memory (ROM), an erasable programmable read-only memory (“EPROM” or Flash memory), a portable compact disc read-only memory (“CD-ROM”), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Code for carrying out operations for embodiments may be written in any combination of one or more programming languages including an object oriented programming language such as Python, Ruby, Java, Smalltalk, C++, or the like, and conventional procedural programming languages, such as the “C” programming language, or the like, and/or machine languages such as assembly languages. The code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (“LAN”) or a wide area network (“WAN”), or the connection may be made to an external computer (for example, through the Internet using an Internet Service Provider).

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, systems, and program products according to embodiments. It will be understood that each block of the schematic flowchart diagrams and/or schematic block diagrams, and combinations of blocks in the schematic flowchart diagrams and/or schematic block diagrams, can be implemented by code. This code may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The code may also be stored in a storage device that can direct a computer, other programmable data processing apparatus, or other devices to function in a particular manner, such that the instructions stored in the storage device produce an article of manufacture including instructions which implement the function/act specified in the schematic flowchart diagrams and/or schematic block diagrams block or blocks.

The code may also be loaded onto a computer, other programmable data processing apparatus, or other devices to cause a series of operational steps to be performed on the computer, other programmable apparatus or other devices to produce a computer implemented process such that the code which execute on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and program products according to various embodiments. In this regard, each block in the schematic flowchart diagrams and/or schematic block diagrams may represent a module, segment, or portion of code, which comprises one or more executable instructions of the code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the Flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and code.

The description of elements in each figure may refer to elements of proceeding figures. Like numbers refer to like elements in all figures, including alternate embodiments of like elements.

As used herein, a list with a conjunction of “and/or” includes any single item in the list or a combination of items in the list. For example, a list of A, B and/or C includes only A, only B, only C, a combination of A and B, a combination of B and C, a combination of A and C or a combination of A, B and C. As used herein, a list using the terminology “one or more of” includes any single item in the list or a combination of items in the list. For example, one or more of A, B and C includes only A, only B, only C, a combination of A and B, a combination of B and C, a combination of A and C or a combination of A, B and C. As used herein, a list using the terminology “one of includes one and only one of any single item in the list. For example, “one of A, B and C” includes only A, only B or only C and excludes combinations of A, B and C. As used herein, “a member selected from the group consisting of A, B, and C,” includes one and only one of A, B, or C, and excludes combinations of A, B, and C.” As used herein, “a member selected from the group consisting of A, B, and C and combinations thereof” includes only A, only B, only C, a combination of A and B, a combination of B and C, a combination of A and C or a combination of A, B and C.

A first aspect and a second aspect of the invention have been defined in the independent claims. Some optional features have been defined in the dependent claims. A portable image capture device is disclosed. A method and computer program product also Perform the functions of the apparatus. A portable image capture device includes a sensor array for capturing a basis image. The sensor array is symmetrical about two perpendicular axes so that the basis image is symmetrical about two perpendicular axes. The portable image capture device includes an image storage module for storing a source image corresponding to the basis image, an image selector for receiving a selected aspect ratio, a pixel modifier module for producing a modified image at the selected aspect ratio, where the modified image is produced from the source image, and a display for displaying the modified image.

In some embodiments, the sensor array is a square array for capturing a square basis image. In other embodiments, the portable image capture device includes a focal point modification module for identifying a focal point of the basis image and focussing on the focal point. In other embodiments, the focal point modification module is adapted to identify the focal point by identifying a predetermined feature in a field of view of the portable image capture device. In other embodiments, the focal point modification module is configured to identify the focal point by varying the distance between a lens module of the device and sensors of the sensor array, and select a focal depth when an image sensed by the sensor array is sharpest about a point or a region in a field of view of the device.

In other embodiments, the portable image capture device includes an aspect ratio generator for producing a plurality of altered images, where each altered image of the plurality of altered images corresponds to a respective one of a plurality of predetermined aspect ratios relative to the focal point. The display is configured to display the plurality of altered images. In other embodiments, the image selector is configured to receive the selected aspect ratio by receiving selection of one of the altered images, and display the selected altered image on the display. In other embodiments, the display is a touchscreen display and the image selector module receive the selected aspect ratio by receiving a touch input, on the display, corresponding to said one of the altered images.

In some embodiments, the portable image capture device includes an aspect ratio generator for identifying pixels in the basis image that fall within at least one of a plurality of predetermined aspect ratios relative to the focal point, where the image storage module stores only the identified pixels. In other embodiments, the image storage module is configured to store the selected aspect ratio as a default aspect ratio.

A computer process for producing a modified image includes capturing a basis image that is symmetrical about two perpendicular axes, where the basis image is captured using a sensor array of a portable image capture device and the sensor array is symmetrical about two perpendicular axes, storing a source image corresponding to the basis image in an image storage module in communication with the sensor array, receiving a selected aspect ratio through an image selector, producing a modified image using a pixel modifier module from the source image according to the selected aspect ratio, and displaying the modified image on a display.

In some embodiments, the sensor array is a square array and capturing the basis image comprises capturing a square basis image. In other embodiments, capturing the basis image includes identifying a focal point of the basis image, focussing on the focal point and capturing the basis image. In other embodiments, identifying the focal point includes identifying a particular feature in a field of view of the portable image capture device. In other embodiments, identifying the focal point includes varying a distance between a lens module of the device and sensors of the sensor array and selecting a focal depth when an image sensed by the sensor array is sharpest about a point or a region in a field of view of the portable image capture device. In other embodiments, the computer process includes producing a plurality of altered images, where each altered image of the plurality of altered images corresponds to a respective one of a plurality of predetermined aspect ratios relative to the focal point and displaying the plurality of altered images on the display.

In other embodiments, receiving the selected aspect ratio includes receiving selection of one of the altered images and displaying the selected altered image on the display. In other embodiments, the display is a touchscreen display and receiving the selected aspect ratio includes receiving a touch input corresponding to said one of the altered images. In other embodiments, storing the source image includes identifying pixels in the basis image that fall within at least one of a plurality of predetermined aspect ratios relative to the focal point and storing only the identified pixels.

Another embodiment includes a program product the includes a computer readable storage medium that stores code executable by a processor. The executable code includes code to capture a basis image that is symmetrical about two perpendicular axes, where the basis image is captured using a sensor array of a portable image capture device and the sensor array is symmetrical about two perpendicular axes, to store a source image corresponding to the basis image in an image storage module in communication with the sensor array, to receive a selected aspect ratio through an image selector, to produce a modified image using a pixel modifier module from the source image according to the selected aspect ratio, and to display the modified image on a display.

In the following description, a portable image capture device is described. Embodiments of the portable image capture device enable framing to be applied during post processing of the image, without affecting the source capture/basis image (i.e. the image as captured by the portable electronic device). Some embodiments also enable framing to be changed. Also, embodiments of the present invention enable a photograph to be taken in either portrait or landscape orientation, without changing hand position. Such embodiments preserve hardware design ergonomics (e.g. the location of a camera flash, physical or virtual buttons on a user interface of the portable image capture device, app widget, etc.).

As used herein, the term ‘culling’ pixels and similar refer to one of, or a combination of, selecting pixels that fall within the aspect ratio (i.e. extracting from an image storage module only those pixels that fall within the aspect ratio) and removing pixels from a copy of the source image.

The term ‘falling within the aspect ratio’ and similar refers to the pixels constituting part of an image having the desired aspect ratio. Where a focal point is used for the image, and the image is formed around that focal point, the pixels falling within the aspect ratio will form part of the image formed around that focal point.

The term ‘default aspect ratio’ and similar refer to an aspect ratio for display of an image that is used until an alternative aspect ratio, or degree of magnification or resolution, is selected. Where the source image is stored using a focal point, the default aspect ratio will be formed with reference to that focal point.

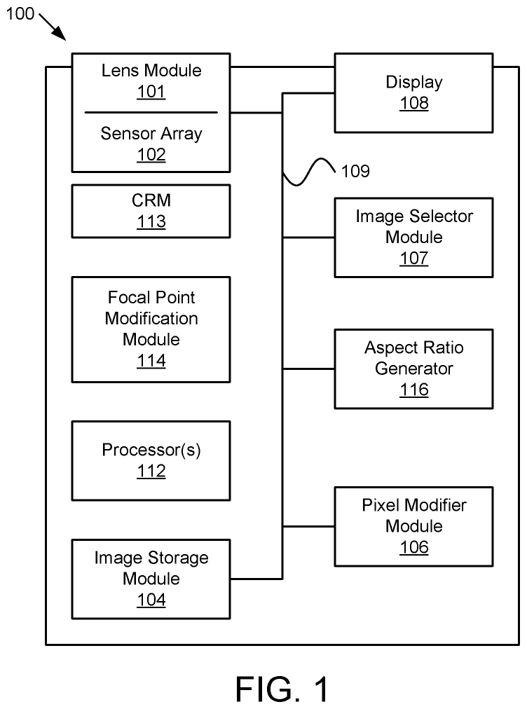

FIG. 1 is a schematic diagram of a portable image capture device 100 in accordance with present teachings. The portable image capture device 100 includes 101: a lens module 101, a sensor array 102, an image storage module 104, a pixel modifier module 106, an image selector module 107, a display 108, a common bus 109, one or more processors 112, a focal point modification module 114 and an aspect ratio generator 116.

The sensor array 102 includes, or is in communication with, a lens module The lens module 101 directs lights to sensors in the sensor array 102. It will be appreciated that a lens module 101 is inherent in all embodiments described herein. The abovementioned components may be in communication via a common bus 109.

It will be appreciated that many different mechanisms may be used in order to trigger capture of a photograph. Some modern triggers for image capture include face and hand gestures, touching a virtual button (e.g. on the display 108), or the more traditional physical buttons, time lapse, or time lapse interval triggering where, for example, a camera takes photos at intervals spaced out over a period of time.

The sensor array 102 is used for capturing a basis image. A “basis image” is a raw image captured by the sensory array 102. The basis image may be pre-processed before being stored in the image storage module 104, as a “source image.” The source image can be later fetched from the image storage module 104 for viewing or for creating a modified image—e.g. by cropping, changing the aspect ratio of the source image, and so forth. In each case, a basis image, source image or any other image will be stored as data representing a visual image, and the skilled person will understand that reference to storage of an image is equivalent to referring to storage of data representing a visual image.

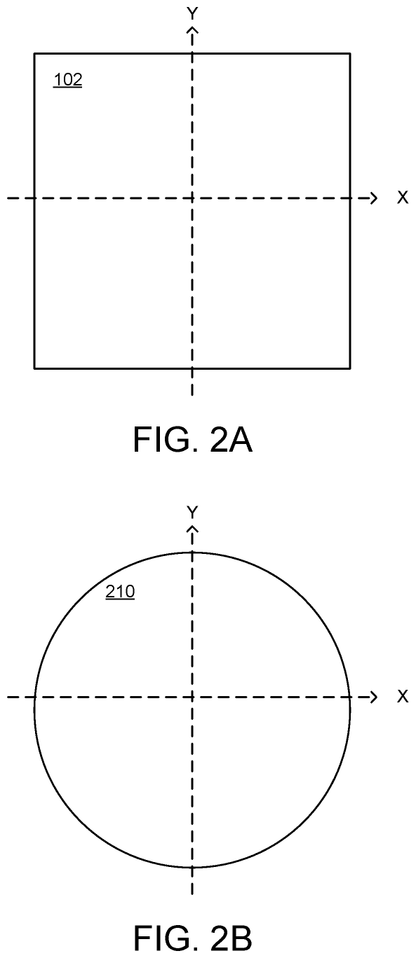

The sensor array 102 is symmetrical about two perpendicular axes X, Y. In the present case, the result is a square sensor array 102 as reflected by FIG. 2A. An alternative sensor array that maintains similar symmetry is sensor array 210, shown in FIG. 2B. For current manufacturing methods, a circular array such as array 210 would be less desirable than a square array, due to there being potentially lower yield resulting from wasted space between arrays. Moreover, cutting the array to size may be difficult, though the cuts need not be the same shape as the array themselves. In contrast, with a square array 102, the arrays can be closely packed during manufacture, with minimal wasted space between adjacent arrays. The following description will generally be made with reference to a square array 102, though it will be appreciated that if a circular array 210 is used, the same discussion will apply.

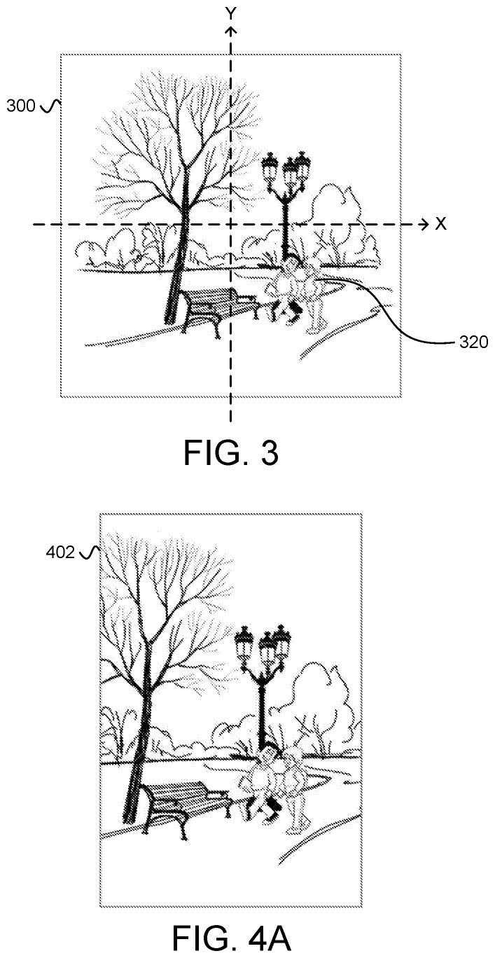

As a result of the symmetry of the sensor array 102, the basis image 300 (see FIG. 3) is similarly symmetrical about two perpendicular axes—presently a square image 300.

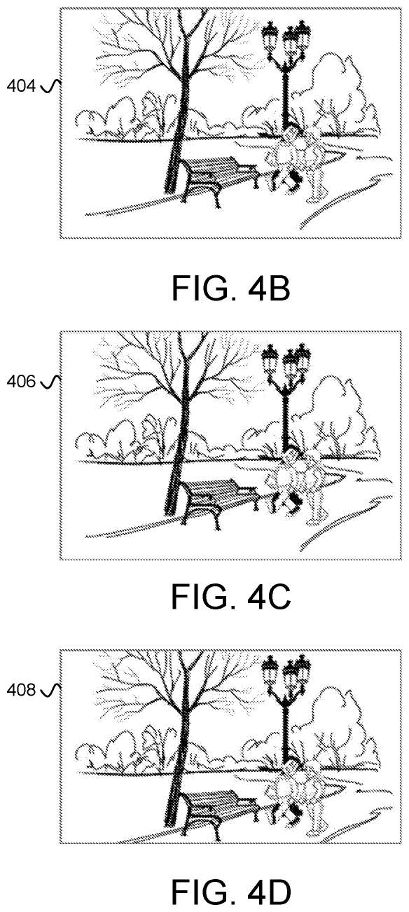

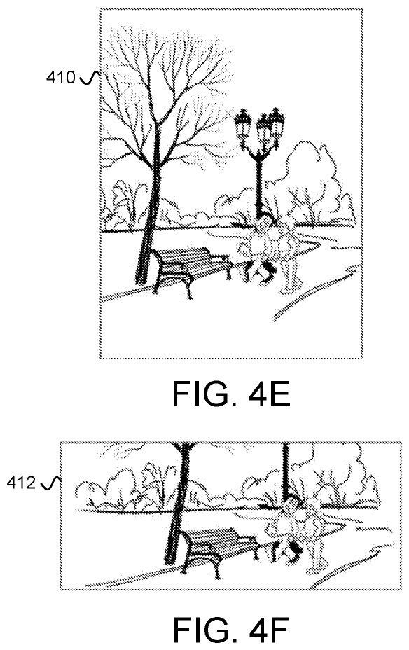

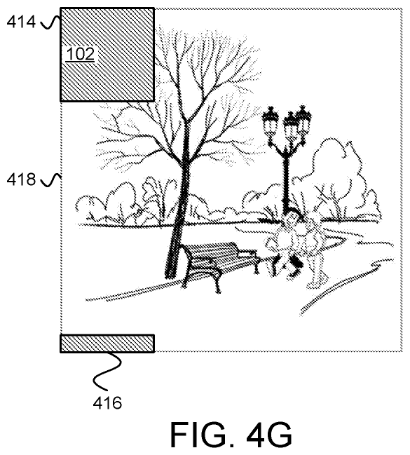

The image storage module 104 is for storing a source image corresponding to the basis image 300. Typically, the source image and basis image will be the same. However, it is envisaged that in some embodiments some pixels of the basis image may not be used in the source image. For example, FIGS. 4A to 4F show altered images 402, 404, 406, 408, 410, 412, corresponding to the source image, each altered image having a different aspect ratio. When all aspect ratios are combined, it may be that some pixels in the corners are not present in any of the aspect ratios—for example, regions 414, 416 of image 418 of FIG. 2g may not be present in any aspect ratio and thus the source image may not include those pixels.

In these cases, the aspect ratio generator 116, in some embodiments, identifies pixels in the basis image that fall within at least one of a plurality of predetermined aspect ratios relative to a focal point 320. The image storage module 104 may then store only the identified pixels. However, to provide greatest flexibility with future changes to the aspect ratio, including using non-standard aspect ratios, and to ensure all aspect ratios remain available even where the focal point is moved, the source image and basis image will typically be the same with no pixels removed to reduce file size at storage.

Once the source image is saved, the image selector 107 can receive a selected aspect ratio. In order to then display the modified image, the pixel modifier module 106 produces the modified image at the selected aspect ratio, from the source image. The modified image is produced by culling pixels from the source image without changing the source image—e.g. the modified image may be a copy of the source image so that the source image itself remains unaltered. The modified image may then be displayed on the display 108.

In general, a photograph will be focussed at a specific focal length or range. Features in an image can become increasingly blurry, or out of focus, the further they are from the focal length. To ensure the modified image is accurately centred, the focal point modification module 114 identifies a focal point of the image—e.g. point 320 of basis/source image 300—and focusses on the focal point. The modified image is then generated using the particular focal point. For example, the modified image may be horizontally or vertically centred on the focal point, or may otherwise be located such that the focal point is within its borders.

The focal point modification module 114 may be adapted to identify the focal point by identifying a particular feature in a field of view of the portable image capture device. That feature may be a feature the movement of which is detected by the portable image capture device 100, or may be selected by the user of the device 100—e.g. by tapping on the focal point on display 108, where display 108 is a touchscreen display. To ensure focus, the focal point modification module 114 may be configured to identify the focal point 320 by trying a plurality of focal depths or distances —e.g. by varying the distance between the lens module 101 and sensors of the sensor array 102—and selecting a focal depth or distance when an image sensed by the sensor array 102 is sharpest, the image comprising a point 320 or a region in a field of view of the portable image capture device 100 (e.g. where no fixed “point” can be separated from the surrounding features in the field of view).

The focal point modification module 114 may also be configured to receive selection of a new focal point (e.g. through a touch command on the new focal point on the source or modified image displayed on the display 108). This will enable the aspect ratio generator 116 to generate altered images based on the new focal point. In other words, the new focal point is only used for aspect ratio framing and cannot alter the original focal point, or focus, used at the time of capture of the basis image.

The aspect ratio generator 116, alternatively or in addition to the functions set out above, may produce the plurality of altered images shown in FIGS. 4A to 4F. The modified image may be one of the altered images. Each altered image shown in FIGS. 4A to 4F corresponds to a respective one of a plurality of predetermined aspect ratios relative to the focal point. In other words, once the focal point has been identified, the aspect ratio generator 116 produces altered images each of which includes the focal point. In another embodiment, the user selects a custom aspect ratio and the aspect ratio generator 116 produces an altered image based on the custom aspect ratio provided by the user.

Once the aspect ratio generator 116 generates the altered images, the display 108 displays one or more of the plurality of altered images. The display 108 may be

configured to display all of the altered images concurrently. To facilitate concurrent display, the display 108 may be configured to display scaled versions of the altered images so that all scaled versions concurrently fit on the display 108—this is reflected by images 4A to 4F being arranged in a generally rectangular arrangement as would be reflected on the rectangular display of a smartphone or other portable image capture device, when held in portrait orientation. This enables a viewer or user to see what the image looks like in each of the aspect ratios, concurrently. Alternatively, the display 108 may be configured to display the altered images sequentially—e.g. by cycling through the images. In either case, the user can select the desired aspect ratio by selecting one of the altered images.

The image selector module 107 receives the selection of the selected aspect ratio or altered image, through any appropriate means. The image selector module 107 may, for example, receive selection through depression of a physical button on the portable image capture device 100. Alternatively, where the display 108 is a touchscreen display, the image selector module 107 may receive the selected aspect ratio by receiving a touch input, on the display 108, corresponding to said one of the altered images—e.g. on the location of the display 108 at which the relevant altered image is displayed.

The image storage module 104 may be configured to store the selected aspect ratio as a default aspect ratio for the source image. Thus, in some cases the source image may be displayed in its symmetrical form—e.g. per FIG. 2—by default, in other cases the selected altered image may be displayed by default. In some cases, the user may select a plurality of altered images considered to be the best framings of the source image. The altered image or images may then be saved in the image storage module 104 separately from the source capture, or may be saved as pointers or indexes that, when applied to the source image, result in production of the relevant altered image.

The user may then choose to share the source image or altered image, e.g. through an app. When shared through an app, the altered image may be sent or the source image may be sent. Alternatively, the source image may be sent with only those pixels displayed, in the app, that fall within the altered image. The app may therefore receive the source image and a pointer or index from which the app can determine which pixels to display. This would enable the recipient to see the altered image the sender thought was the best framing for the source image, yet the recipient would still be able to view other framings to see if an alternative is more suitable.

Where the sensor array 102 is circular, per FIG. 2B (e.g. array 210), the altered images may also be easily rotated when determining best framing. This may remove misalignment that may occur between, for example, the bottom of a rectangular display and the horizon when taking a photograph using a rectangular or square sensor array.

Using portable image capture device 100 to retain the square source image, the source image can be post-processed to change aspect ratio, orientation and other characteristics. With known technologies, this is not possible except at the cost of significant loss of image content. For example, to change a photograph from portrait orientation to landscape orientation would mean the long side of the landscape photograph would be, at most, the same length as the short side of the portrait photograph.

The portable image capture device 100, which may be a smartphone, digital camera, or other device, can therefore be consistently held in the orientation that best suits ergonomics or for ease of use—e.g. if a device is designed to be held in portrait orientation, the user may do so and yet take photographs with high resolution, that are suitable for production in landscape orientation.

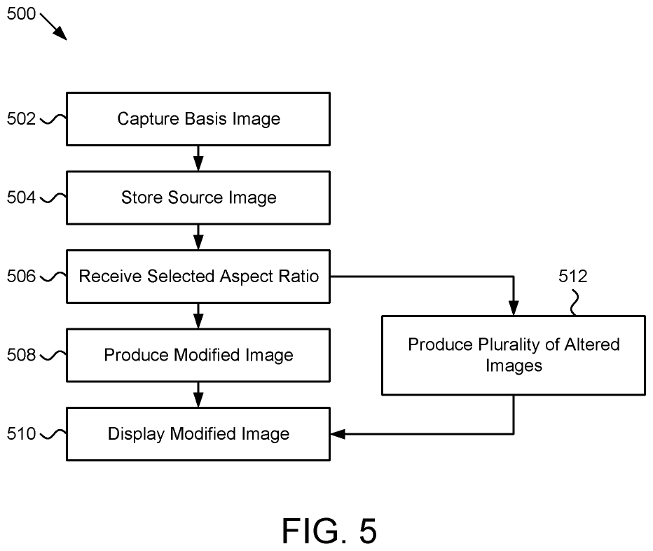

The modules set out in FIG. 1 are thus collectively designed to implement a computer process 500 for producing a modified image, as shown in FIG. 5. The computer process 300 broadly comprises:

Step 502: capturing a basis image that is symmetrical about two perpendicular axes, using the sensor array 102 of portable image capture device 100, the sensor array 102 being symmetrical about two perpendicular axes;

Step 504: storing the source image, which corresponds to the basis image, in the image storage module 104 that is in communication with the sensor array 102;

Step 506: receiving a selected aspect ratio through the image selector or image selector module 107 (the terms image selector and image selector module being used interchangeably herein);

Step 508: producing a modified image using a pixel modifier module 106, by culling pixels from the source image according to the selected aspect ratio; and

Step 510: displaying the modified image on the display 108.

With particular regard to the embodiment shown in FIG. 1, the sensor array 102 is a square array and thus capturing the basis image comprises capturing a square basis image. The capturing process may include: identifying a focal point 320 of the image, focussing on the focal point, and capturing the basis image.

In the process 500, the focal point 320 may be identified in a variety of Ways. For example, identifying the focal point 320 may include identifying a particular feature in a field of view of the portable image capture device 100. The field of view is the environment visible to the camera that will form part of the basis image when it is captured. Alternatively, or in addition, identifying the focal point 320 may include trying a plurality of focal depths or distances—e.g. by varying the distance between the lens module 101 and sensors of the sensor array 102—and selecting a focal depth or distance when an image sensed by the sensor array 102 is sharpest, the image comprising a point 320 or a region in a field of view of the portable image capture device 100 (e.g. where no fixed “point” can be separated from the surrounding features in the field of view).

The portable image device may similarly be configured to perform step 512 by producing a plurality of altered images, each altered image of the plurality of altered images corresponding to a respective one of a plurality of predetermined aspect ratios relative to the focal point 320, and the modified image being one of the altered images, and displaying the plurality of altered images on the display.

Step 508 may thus be achieved by receiving selection of one of the altered images. Where the display 108 is a touchscreen display, step 508 may comprise receiving a touch input corresponding to one of the altered images.

Step 504, storing the source image, may involve identifying pixels in the basis image that fall within at least one of the plurality of predetermined aspect ratios relative to the focal point, as mentioned above, and storing only the identified pixels. However, this may be undesirable in some cases since it reduces the flexibility of making future modifications to copies of the source image, particularly where those modification would otherwise produce images comprises pixels that were not saved in the source image. Step 504 may further involve storing the selected aspect ratio as a default aspect ratio.

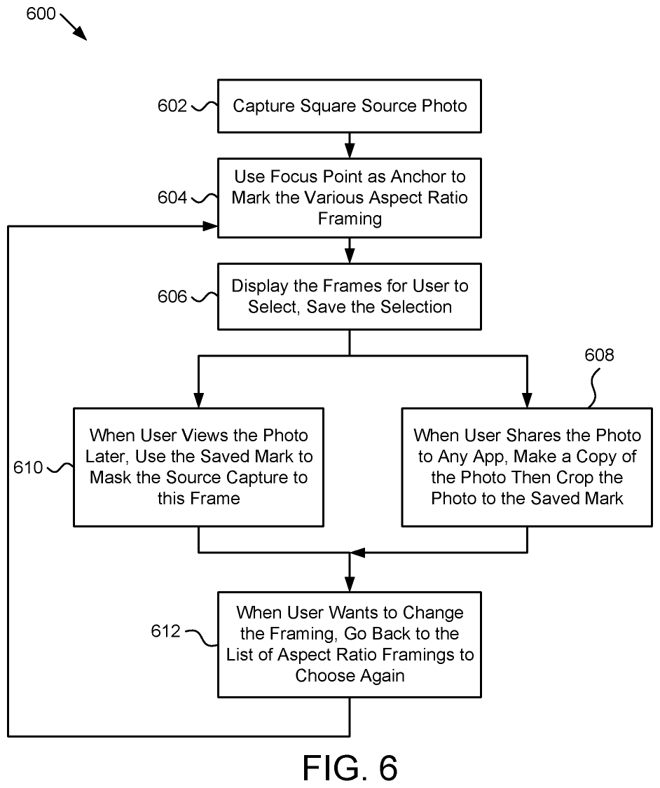

A similar process 600 is set out in FIG. 6. Step 602 involves capturing the basis image or capturing the source image where the source image is the same as the basis image. The focal point 320 is then identified, per step 604, and is used to anchor the various aspect ratio framing. The various frames—altered images corresponding to the respective aspect ratios—are then displayed for the user to select, per step 606, an example of which display is illustrated by FIGS. 4A to 4F. The selected aspect ratio may then be saved as the preferred aspect ratio (modified image) of the source image, or as a separate image altogether.

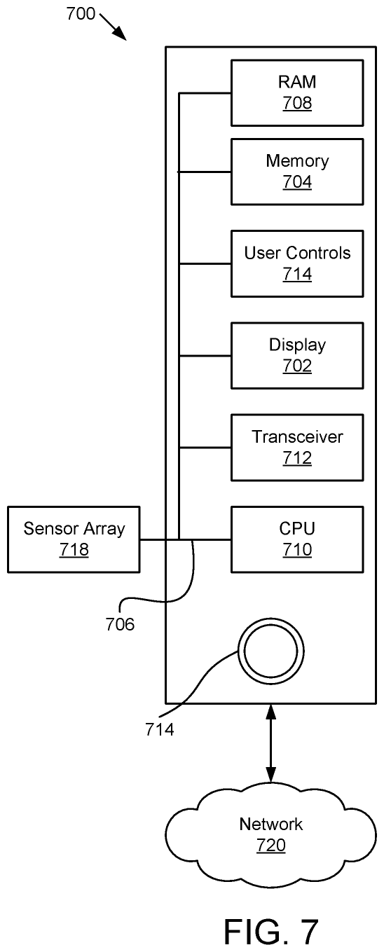

Per step 610, the user may later view the photo by extracting it from image storage 104. The photo may be extracted as a source image, with the selected aspect ratio (and focal point 320) being used as a saved mark to mask the source image to the desired aspect ratio. In some embodiments, the user may instead, or also, desire to share the image—e.g. through an app per step 610. A copy of the source image may then be taken and the saved mark or selected aspect ratio then may be used to crop the copy to the desired aspect ratio for sending via network 720 of FIG. 7, which receives data from transceiver(s) 712.

The network 720 may be a wired or optical network. In one embodiment, the network 720 includes a wireless connection. The wireless connection may be a mobile telephone network. The wireless connection may also employ a Wi-Fi network based on any one of the Institute of Electrical and Electronics Engineers (IEEE) 802.11 standards. Alternatively, the wireless connection may be a BLUETOOTH® connection. In addition, the wireless connection may employ a Radio Frequency Identification (RFID) communication including RFID standards established by the International Organization for Standardization (ISO), the International Electrotechnical Commission (IEC), the American Society for Testing and Materials® (ASTM®), the DASH7™ Alliance, and EPCGlobal™.

Alternatively, the wireless connection may employ a ZigBee® connection based on the IEEE 802 standard. In one embodiment, the wireless connection employs a Z-Wave® connection as designed by Sigma Designs®. Alternatively, the wireless connection may employ an ANT® and/or ANT+® connection as defined by Dynastream® Innovations Inc. of Cochrane, Canada.

The wireless connection may be an infrared connection including connections conforming at least to the Infrared Physical Layer Specification (IrPHY) as defined by the Infrared Data Association® (IrDA®). Alternatively, the wireless connection may be a cellular telephone network communication. All standards and/or connection types include the latest version and revision of the standard and/or connection type as of the filing date of this application.

In another embodiment, in step 608, when a user shares a photo to an application, the process 600 may make a copy of the source image and then may crop the copy of the source image based on the saved mark. The user can make further adjustments to the framing, per step 612. This may involve, for example, adjusting the focal point 320, selecting an alternative, non-standard aspect ratio etc.

In one or more exemplary embodiments, the functions or operations described herein may be implemented in hardware, software, firmware, or any combination thereof. If implemented in software, the functions may be stored on or transmitted over as one or more instructions or code encoded on a non-transitory computer-readable medium such as medium 113 of FIG. 1, or memory 704 of FIG. 7. Non-transitory computer-readable medium 113, or memory 704, can include both computer storage medium and communication medium including any medium that facilitates transfer of a computer program from one place to another. A storage medium may be any available medium that can be accessed by a computer.

The non-transitory computer readable storage medium 113, 704 may embody a program of computer readable instructions. Those instructions, when executed by one or more data processors, such as processor(s) 112 of FIG. 1 or central processing unit 710 of FIG. 7, of a portable image capture device 100 comprising a sensor array 102, 718 that is symmetrical about two perpendicular axes, causes the one or more data processors 112, 710 to perform the computer process as described with reference to FIG. 5 and/or FIG. 6. The sensor array 718 will be understood to include, or be in communication with, a lens module 101 for directing light to sensors of the sensor array 718. The lens module 101 may also be used to adjust focal length e.g. by changing a distance between the lens and sensors of the sensor array 718.

In this regard, FIG. 7 is a block diagram showing an exemplary computer device 700, which may correspond to computer system 100, in which embodiments of the invention may be practiced. The computer device 700 may be a mobile computer device such as a smart phone, a wearable device, a drone (e.g. unmanned aerial vehicle) image capture device, a palm-top computer, multimedia Internet enabled cellular telephones, and the like. For ease of description, the computer device is described below, by way of non-limiting example, with reference to a mobile device in the form of an iPhone® manufactured by Apple®, Inc or one manufactured by LG®, HTC® and Samsung®, for example.

As shown, the mobile computer device 700 includes the following components in electronic communication via a bus 706: a display 702, non-volatile (non-transitory) memory 704, random access memory (“RAM”) 708, N processing components 710, a transceiver component 712 that includes N transceivers, and user controls 714. The one or more processors 112 of computing device 100 may be performed by the N processing components 710 of mobile computer device 700, for example.

Although the components depicted in FIG. 7 represent physical components, FIG. 7 is not intended to be a hardware diagram. Thus, many of the components depicted in FIG. 7 may be realized by common constructs or distributed among additional physical components. Moreover, it is certainly contemplated that other existing and yet-to-be developed physical components and architectures may be utilized to implement the functional components described with reference to FIG. 7.

The display 702 generally operates to provide a presentation of content to a user, and may be realized by any of a variety of displays (e.g., CRT, LCD, HDMI, micro-projector and OLED displays). It may also facilitate selection of content, e.g. an altered image as the modified image as described with reference to step 506, via touch commands, where display 702 is a touchscreen display.

In general, the non-volatile data storage 704 (also referred to as non-volatile memory) functions to store (e.g., persistently store) data and executable code. In some embodiments for example, the non-volatile memory 704 includes bootloader code, modem software, operating system code, file system code, and code to facilitate the implementation components, well known to those of ordinary skill in the art, which are not depicted nor described for simplicity. In many implementations, the non-volatile memory 704 is realized by flash memory (e.g., NAND or ONENAND memory), but it is certainly contemplated that other memory types may be utilized as well. Although it may be possible to execute the code from the non-volatile memory 704, the executable code in the non-volatile memory 704 is typically loaded into RAM 708 and executed by one or more of the N processing components 710.

The N processing components 710 in connection with RAM 708 generally operate to execute the instructions stored in non-volatile memory 704. As one of ordinarily skill in the art will appreciate, the N processing components 710 may include a video processor, modem processor, DSP, graphics processing unit (GPU), and other processing components.

The transceiver component 712 includes N transceiver chains, which may be used for communicating with external devices via wireless networks. Each of the N transceiver chains may represent a transceiver associated with a particular communication scheme. For example, each transceiver may correspond to protocols that are specific to local area networks, cellular networks (e.g., a CDMA network, a GPRS network, a UMTS networks), and other types of communication networks. The computer device 700 further includes a sensor array 718, being symmetrical about two perpendicular axes as described with reference to FIG. 1.

It should be recognized that FIG. 7 is merely exemplary and in one or more exemplary embodiments, the functions described herein may be implemented in hardware, software, firmware, or any combination thereof. If implemented in software, the functions may be stored on or transmitted over as one or more instructions or code encoded on a non-transitory computer-readable medium 704. The non-transitory computer-readable medium 704 includes both computer storage medium and communication medium including any medium that facilitates transfer of a computer program from one place to another. A storage medium may be any available medium that can be accessed by a computer.

Throughout this specification, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference to any prior art in this specification is not, and should not be taken as, an acknowledgment or any form of suggestion that the prior art forms part of the common general knowledge.

What is claimed is:

1. A portable image capture device comprising:
a sensor array for capturing a basis image, the sensor array being symmetrical about two perpendicular axes so that the basis image is symmetrical about two perpendicular axes;
an image storage module for storing a source image corresponding to the basis image;
an image selector for receiving a selected aspect ratio;
a pixel modifier module for producing a modified image at the selected aspect ratio, the modified image being produced from the source image; and
a display for displaying the modified image.

2. The device of claim 1, wherein the sensor array is a square array for capturing a Square basis image.

3. The device of claim 1, further comprising a focal point modification module for: identifying a focal point of the basis image; and focussing on the focal point.

4. The device of claim 3, wherein the focal point modification module is adapted to identify the focal point by identifying a predetermined feature in a field of view of the portable image capture device.

5. The device of claim 3, wherein the focal point modification module is configured to:
identify the focal point by varying the distance between a lens module of the device and sensors of the sensor array; and
select a focal depth when an image sensed by the sensor array is sharpest about a point or a region in a field of view of the device.

6. The device of claim 3, further comprising an aspect ratio generator for producing a plurality of altered images, each altered image of the plurality of altered images corresponding to a respective one of a plurality of predetermined aspect ratios relative to the focal point, wherein the display is configured to display the plurality of altered images.

7. The device of claim 6, wherein the image selector is configured to receive the selected aspect ratio by receiving selection of one of the altered images and display the selected altered image on the display.

8. The device of claim 7, wherein the display is a touchscreen display and the image selector module receive the selected aspect ratio by receiving a touch input, on the display, corresponding to said one of the altered images.

9. The device of claim 1, further comprising an aspect ratio generator for identifying pixels in the basis image that fall within at least one of a plurality of predetermined aspect ratios relative to the focal point, wherein the image storage module stores only the identified pixels.

10. The device of claim 1, wherein the image storage module is configured to store the selected aspect ratio as a default aspect ratio.

11. A computer process for producing a modified image, the process comprising:
capturing a basis image that is symmetrical about two perpendicular axes, wherein the basis image is captured using a sensor array of a portable image capture device, the sensor array being symmetrical about two perpendicular axes;
storing a source image corresponding to the basis image in an image storage module in communication with the sensor array;
receiving a selected aspect ratio through an image selector;
producing a modified image using a pixel modifier module from the source image according to the selected aspect ratio; and
displaying the modified image on a display.

12. The computer process of claim 11, wherein the sensor array is a square array and capturing the basis image comprises capturing a square basis image.

13. The computer process of claim 11, wherein capturing the basis image comprises:
identifying a focal point of the basis image;
focussing on the focal point; and
capturing the basis image.

14. The computer process of claim 13, wherein identifying the focal point comprises identifying a particular feature in a field of view of the portable image capture device.

15. The computer process of claim 13, wherein:
identifying the focal point comprises varying a distance between a lens module of the device and sensors of the sensor array; and
selecting a focal depth when an image sensed by the sensor array is sharpest about a point or a region in a field of view of the portable image capture device.

16. The computer process of claim 13, further comprising:
producing a plurality of altered images, each altered image of the plurality of altered images corresponding to a respective one of a plurality of predetermined aspect ratios relative to the focal point; and
displaying the plurality of altered images on the display.

17. The computer process of claim 16, wherein receiving the selected aspect ratio comprises receiving selection of one of the altered images and displaying the selected altered image on the display.

18. The computer process of claim 17, wherein the display is a touchscreen display and receiving the selected aspect ratio comprises receiving a touch input corresponding to said one of the altered images.

19. The computer process of claim 13, wherein storing the source image comprises:
identifying pixels in the basis image that fall within at least one of a plurality of predetermined aspect ratios relative to the focal point; and
storing only the identified pixels.

20. A program product comprising a computer readable storage medium that stores code executable by a processor, the executable code comprising code to:
capture a basis image that is symmetrical about two perpendicular axes, wherein the basis image is captured using a sensor array of a portable image capture device, the sensor array being symmetrical about two perpendicular axes;
store a source image corresponding to the basis image in an image storage module in communication with the sensor array;
receive a selected aspect ratio through an image selector;
produce a modified image using a pixel modifier module from the source image according to the selected aspect ratio; and
display the modified image on a display.
